(19) United States
(12) Patent Application Publication
(10) Pub. No.: US 2004/0256635 A1
(43) Pub. Date: Dec. 23, 2004

(54) Hetero bipolar transistor

(75) Inventors: Tohru Saitoh, Osaka (JP); Shigetaka Aoki, Osaka (JP); Katsuya Nozawa, Osaka (JP); Teruhito Ohnishi, Osaka (JP)

Correspondence Address: McDERMOTT, WILL & EMERY, 600 13th Street, N.W., Washington, DC, 20005-3096, US

(73) Assignee: Matsushita Electric Industrial Co., Ltd., Osaka (JP)

(21) Appl. No.: 10/689,646

(22) Filed: Oct. 22, 2003

Related U.S. Application Data
(63) Continuation of application No. PCT/JP02/12951, filed on Dec. 11, 2002.

(30) Foreign Application Priority Data
Dec. 11, 2001 (JP) 2001-377112

(51) Int. Cl. H01L 31/0328

(52) U.S. Cl. 257/197

(57) ABSTRACT

In a hetero bipolar transistor according to the present invention, a SiGe spacer layer (40), a SiGe graded layer (41) having a portion functioning as a base layer and composed of a plurality of sublayers having different Ge composition ratios, and a Si cap layer (42) are formed on a collector layer (12) formed in a portion of a Si substrate (10). In the SiGe graded layer (41), when the thickness of each sublayer is larger, the number of sublayers is smaller, and difference in Ge composition ratio between adjacent sublayers is larger, measurement of the thickness of each sublayer becomes easier. However, in order to avoid degradation of a cut-off frequency characteristic of a device, the film thickness of each sublayer needs to be approximately 20 nm or less, and the number of sublayers is preferably 2 or more.

This is a continuation application under 35 U.S.C.111(a) of pending prior International Application No. PCT/JP02/12951, filed on Dec. 11, 2002.

### BACKGROUND OF THE INVENTION

1. Field of the Invention

The present invention relates to a hetero bipolar transistor fabricated by epitaxially growing crystal different from crystal of a substrate.

2. Description of the Related Art

In recent years, development of hetero bipolar transistors (HBTs) have been made at rapid paces. The HBT is configured to include a heterojunction structure such as Si (silicon)/SiGe (silicon germanium), Si/SiC (silicon carbon), or the like in a bipolar transistor formed on a silicon substrate, for the purpose of improving conduction property to enable an operation in a higher frequency range. This HBT has a SiGe heterojunction structure formed by epitaxially growing a SiGe layer on the Si substrate. This enables a transistor to operate in a high frequency range. Such operation has been achieved only by a transistor using a compound semiconductor substrate such as GaAs (gallium arsenic). Since the HBT is made of materials having good compatibility with general-purpose silicon processes, such as the Si substrate and the SiGe layer, large-scale integration and a low cost are advantageously achieved.

Hereinafter, a structure of the conventional HBT will be described with reference to FIG. 17. FIG. 17 is a sectional view showing a structure of the conventional hetero bipolar transistor.

As shown in FIG. 17, in the conventional hetero bipolar transistor, an upper portion of a Si substrate 100 has a retrograde well 101 having a depth of 1 μm and containing an N-type impurity. As isolation, a shallow trench 103 in which silicon oxide is embedded and a deep trench 104 comprised of an undoped polysilicon film 105 and a silicon oxide film 106 surrounding the undoped polysilicon film 105 are provided.

A collector layer 102 is provided in a region within the Si substrate 100 that is sandwiched between shallow trenches 103. An n⁺ collector plug layer 107 is provided in a region within the Si substrate 100 which is isolated from the collector layer 102 by the shallow trench 103, for connection to an electrode of the collector layer 102 through the retrograde well 101.

A first deposited oxide film 108 having a collector opening 110 with a thickness of approximately 30 nm is provided on the Si substrate 100. A base forming layer 111 comprised of a SiGe spacer layer 130, a SiGe graded layer 131, and a Si cap layer 132 is formed on a portion of an upper surface of the Si substrate 100 which is exposed to the collector opening 110. The base forming layer 111 is formed by selective growth only on a portion of the Si substrate 100 which is exposed to the collector opening 110. Only a lower portion of a center portion of the base forming layer 111 functions as an intrinsic base 119. And, an upper portion of the center portion of the base forming layer 111 functions as an emitter layer. Most of the SiGe spacer layer 130 and the SiGe graded layer 131 of the base forming layer 111 are doped with a p-type impurity such as boron (B) at approximately 2×10¹⁸ atoms·cm⁻³, while the Si cap layer 132 is doped by diffusion of an n-type impurity such as phosphorous (P) from an n⁺ polysilicon layer 129 in the distribution from approximately 1×10²⁰ atoms·cm⁻³ to 1×10¹⁷ atoms·cm,⁻³ from top to bottom in the depth direction of the substrate.

A second deposited oxide film 112 having a thickness of 30 nm and functioning as an etching stopper is provided on the first deposited oxide film 108 and the base forming layer 111. A base junction opening 114 and a base opening 118 are formed in the second deposited oxide film 112. And, a p⁺ polysilicon layer 115 having a thickness of approximately 150 nm and a third deposited oxide film 117 are provided such that the p⁺ polysilicon layer 115 extends over the second deposited oxide film 112 to fill the base junction opening 114. A portion of the base forming layer 111 excluding a region located under the base opening 118 and the p⁺ polysilicon layer 115 form an extrinsic base 116.

Portions of the p⁺ polysilicon layer 115 and the third deposited oxide film 117 which are located above the base opening 118 of the second deposited oxide film 112 are configured to open. Fourth deposited oxide films 120 having a thickness of approximately 30 nm are formed on side faces of the p⁺ polysilicon layer 115. On the fourth deposited oxide films 120, side walls 121 made of polysilicon with a thickness of approximately 100 nm are provided. An n⁺ polysilicon layer 129 extends over the third deposited oxide film 117 to fill the base opening 118. The n⁺ polysilicon layer 129 functions as an emitter plug electrode. Outer side faces of the n⁺ polysilicon layer 129 and the p⁺ polysilicon layer 115 are covered with side walls 123.

Ti (titanium) silicide layers 124 are formed on surfaces of the n⁺ collector plug layer 107, the p⁺ polysilicon layer 115, and the n⁺ polysilicon layer 129, respectively.

The entire substrate is covered with an interlayer dielectric 125. Through the interlayer dielectric 125, contact holes respectively extend to reach the n⁺ collector plug layer 107, the p⁺ polysilicon layer 115 as part of the extrinsic base, and the Ti silicide layer 124 of the n⁺ polysilicon layer 129 as the emitter plug electrode. The contact holes are filled with W plugs 126. Metal wires 127 are respectively connected to the W plugs 126 and extend on the interlayer dielectric 125.

In the SiGe graded layer 131 of the base forming layer 111 functioning as a base, Ge composition ratio decrease in a direction from the SiGe spacer layer 130 to the SiGe cap layer 132, thereby enabling formation of a base region having a composition graded such that a band gap of the base region decreases gradually in a direction from an emitter region to a collector region. By an electric field generated by such a graded composition, carriers injected into the base layer are accelerated and travel in a drifting manner within the base layer. Since this drifting electric field can increase a carrier velocity more than diffusion does, time during which carriers travel is reduced. Consequently, cut-off frequency (fT) is improved.

However, the conventional hetero bipolar transistor described above has the following disadvantages.

As shown in FIG. 17, when the base forming layer 111 functioning as the base is comprised of three layers of the SiGe spacer layer 130, the SiGe graded layer 131, and the Si cap layer 132, it is difficult to measure the film thickness of each layer and hence to know accurate film thickness of each layer. For this reason, values of film thicknesses of layers measured using, for example, a spectroscopic ellipsometer or the like have large errors and variations. Therefore, when the devices are mass-produced, the confirmation of layer formation and process control are difficult.

Under these circumstances, the present invention has been developed, and an object of the present invention is to provide a hetero bipolar transistor in which measurement accuracy of film thickness of each of layers forming a base portion can be improved by changing a Ge composition pattern in a base forming layer.

### SUMMARY OF THE INVENTION

In order to achieve the above-described object, a hetero bipolar transistor according to the present invention, comprises a semiconductor substrate; a first semiconductor layer formed on the semiconductor substrate and comprised of a crystal containing silicon and germanium; a second semiconductor layer formed on the first semiconductor layer and comprised of a crystal containing silicon and germanium, at least a portion of the second semiconductor layer functioning as a base layer; and a third semiconductor layer formed on the second semiconductor layer and comprised of a crystal containing silicon, at least a portion of the third semiconductor layer functioning as an emitter layer, wherein the second semiconductor layer includes regions each having a germanium composition ratio that varies stepwisely with a difference of 2.5% or more, in the vicinity of a boundary between the first semiconductor layer and the second semiconductor layer and a boundary between the second semiconductor layer and the third semiconductor layer.

A hetero bipolar transistor according to the present invention comprises a semiconductor substrate; a first semiconductor layer formed on the semiconductor substrate and comprised of a crystal containing silicon and germanium; a second semiconductor layer formed on the first semiconductor layer and comprised of a crystal containing silicon and germanium, at least a portion of the second semiconductor layer functioning as a base layer; and a third semiconductor layer formed on the second semiconductor layer and comprised of a crystal containing silicon, at least a portion of the third semiconductor layer functioning as an emitter layer, wherein the second semiconductor layer includes a region having a germanium composition ratio that varies stepwisely with a difference of 2.5% or more, in the vicinity of a boundary between the first semiconductor layer and the second semiconductor layer.

A hetero bipolar transistor according to the present invention comprises a semiconductor substrate; a first semiconductor layer formed on the semiconductor substrate and comprised of a crystal containing silicon and germanium; a second semiconductor layer formed on the first semiconductor layer and comprised of a crystal containing silicon and germanium, at least a portion of the second semiconductor layer functioning as a base layer; and a third semiconductor layer formed on the second semiconductor layer and comprised of a crystal containing silicon, at least a portion of the third semiconductor layer functioning as an emitter layer, wherein the second semiconductor layer includes a region having a germanium composition ratio that varies stepwisely with a difference of 2.5% or more, in the vicinity of a boundary between the second semiconductor layer and the third semiconductor layer.

In the hetero bipolar transistor according to the present invention, it is preferable that the second semiconductor layer contains silicon, germanium, and carbon.

In the hetero bipolar transistor according to the present invention, it is preferable that the second semiconductor layer is comprised of a plurality of sublayers having different germanium composition ratios, and the number of the sublayers is not less than 2 and not more than 6.

Preferably, the hetero bipolar transistor according to the present invention, further comprises a marker layer formed between the first semiconductor layer and the second semiconductor layer, wherein the marker layer has a germanium composition ratio lower or higher than a germanium composition ratio of the first semiconductor layer by 2.5% or more and is comprised of a crystal containing at least silicon and germanium.

Preferably, the hetero bipolar transistor according to the present invention further comprises a marker layer formed between the second semiconductor layer and the third semiconductor layer, wherein the marker layer has a germanium composition ratio higher than a germanium composition ratio of the third semiconductor layer by 2.5% or more and is comprised of a crystal containing at least silicon and germanium.

A hetero bipolar transistor according to the present invention comprises a semiconductor substrate; a first semiconductor layer formed on the semiconductor substrate and comprised of a crystal containing silicon and germanium; a second semiconductor layer formed on the first semiconductor layer and comprised of a crystal containing silicon and germanium, at least a portion of the second semiconductor layer functioning as a base layer; and a third semiconductor layer formed on the second semiconductor layer and comprised of a crystal containing silicon, at least a portion of the third semiconductor layer functioning as an emitter layer, wherein the second semiconductor layer includes regions each having a bandgap that varies stepwisely with a difference of 18 meV or more in the vicinity of a boundary between the first semiconductor layer and the second semiconductor layer and a boundary between the second semiconductor layer and the third semiconductor layer.

A method of measuring a thickness of a semiconductor layer in a hetero bipolar transistor according to the present invention including: a semiconductor substrate; a first semiconductor layer formed on the semiconductor substrate and comprised of a crystal containing silicon and germanium, the germanium having a constant concentration; a second semiconductor layer formed on the first semiconductor layer and comprised of a crystal containing silicon and germanium, at least a portion of the second semiconductor layer functioning as a base layer; and a third semiconductor layer formed on the second semiconductor layer and comprised of a crystal containing silicon, at least a portion of the third semiconductor layer functioning as an emitter layer, the method comprising measuring a thickness of the second semiconductor layer, wherein the second semiconductor layer is comprised of a plurality of sublayers, a composition ratio of germanium contained in a first sublayer is different from a composition ratio of germanium contained in a second sublayer adjacent to the first sublayer, and a first boundary between the first semiconductor layer and a sublayer of the second semiconductor layer which is adjacent to the first semiconductor layer, where the composition ratio of germanium varies discontinuously, and a second boundary between the third semiconductor layer and a sublayer of the second semiconductor layer which is adjacent to the third semiconductor layer, where composition ratio of germanium varies discontinuously, are detected by using a spectroscopic ellipsometer, to define a distance between the first boundary and the second boundary as the thickness of the second semiconductor layer.

In the method of measuring a thickness of a semiconductor layer in a hetero bipolar transistor according to the present invention, it is preferable that each of the plurality of sublayers contains germanium of a composition ratio of 1.5% or more, and a difference in composition ratio between the germanium contained in the first sublayer and a composition ratio of the germanium contained in the second sublayer is 1.5% or more.

In the method of measuring a thickness of a semiconductor layer in a hetero bipolar transistor according to the present invention, it is preferable that each of the plurality of sublayers contains germanium of a composition ratio of 2.5% or more, and a difference in composition ratio between the germanium contained in the first sublayer and the germanium contained in the second sublayer is 2.5% or more.

The above and further objects and features of the invention will more fully be apparent from the following detailed description with accompanying drawings.

### BRIEF DESCRIPTION OF THE DRAWINGS

FIG. 1A is a graph showing Ge composition in a base portion of the conventional hetero bipolar transistor, and FIG. 1B is a graph showing Ge composition in a base portion of a hetero bipolar transistor according to the present invention;

FIG. 2 is a view schematically showing variation in Ge composition ratio of a SiGe graded layer composed of 9 sublayers according to the present invention;

FIG. 3A is a view showing a result of film thickness of a Si cap layer in a base forming layer which is measured using a spectroscopic ellipsometer in the present invention, FIG. 3B is a view showing a result of film thickness of a SiGe graded layer in the base forming layer which is measured using the spectroscopic ellipsometer, and FIG. 3C is a view showing a result of film thickness of a SiGe spacer layer in the base forming layer which is measured using the spectroscopic ellipsometer;

FIG. 4 is a view schematically showing variation in Ge composition ratio in the SiGe graded layer composed of 3 sublayers according to the present invention;

FIG. 5A is a view showing a result of film thickness of the Si cap layer in the base forming layer which is measured using the spectroscopic ellipsometer in the present invention, FIG. 5B is a view showing a result of film thickness of the SiGe graded layer in the base forming layer which is measured using the spectroscopic ellipsometer, and FIG. 5C is a view showing a result of film thickness of the SiGe spacer layer in the base forming layer which is measured using the spectroscopic ellipsometer;

FIG. 6 is a view schematically showing patterns of sublayers in the SiGe graded layer according to the present invention;

FIG. 7 is a table listing measurement results of a device characteristic obtained when the number of sublayers in the SiGe graded layer is varied in the present invention;

FIG. 8A is a graph showing the relationshiphip between the number of sublayers and cut-off frequencies (fT) of devices measured by simulation, and FIG. 8B is a graph showing the relationship between film thicknesses of sublayers in the SiGe graded layer and cut-off frequencies (fT) of devices measured by simulation;

FIG. 9 is a table listing the number of sublayers in the SiGe graded layer having a thickness of 40 nm and measured values of cut-off frequencies (fT) of devices;

FIG. 10A is a graph showing measurement results of device characteristics relative to different number of sublayers composing the SiGe graded layers having Ge composition ratio raging from 0% to 10%, and FIG. 10B is a graph showing measurement results of the device characteristics relative to different film thicknesses of sublayers composing the SiGe graded layers;

FIG. 11A is a graph showing measurement results of device characteristics relative to different number of sublayers composing SiGe graded layers having Ge composition ratios raging from 0% to 20%, and FIG. 11B is a graph showing measurement results of device characteristics relative to different film thicknesses of sublayers composing the SiGe graded layers;

FIG. 12 is a cross-sectional view showing a structure of a hetero bipolar transistor according to an embodiment 1 of the present invention;

FIG. 13 is a graph showing results of variation in Ge composition ratio of the SiGe graded layer according to the embodiment 1 of the present invention which is measured using SIMS (Secondary Ion Mass Spectroscopy);

FIG. 14A is a view schematically showing Ge composition ratios of sublayers of a base forming layer according to an example 1, FIG. 14B is a table listing results of device characteristics according to the example 1, and FIG. 14C is a graph showing measurement results of the device characteristics according to the example 1;

FIG. 15A is a view schematically showing Ge composition ratios of sublayers of a base forming layer according to an example 2, FIG. 15B is a table listing measurement results of device characteristics according to the example 2, and FIG. 15C is a graph showing measurement results of the device characteristics according to the example 2;

FIG. 16A is a view schematically showing Ge composition ratios of sublayers of a base forming layer according to an example 3, FIG. 16B is a table listing measurement results of device characteristics according to the example 3, and FIG. 16C is a graph showing measurement results of the device characteristics according to the example 3;

FIG. 17 is a cross-sectional view showing a structure of the conventional hetero bipolar transistor.

### DETAILED DESCRIPTION OF THE PREFERRED EMBODIMENTS

Hereinbelow, embodiments of the present invention will be described with reference to the drawings.

Consideration of Ge Composition Patterns in Base Forming Layer and Experimental Results Thereof

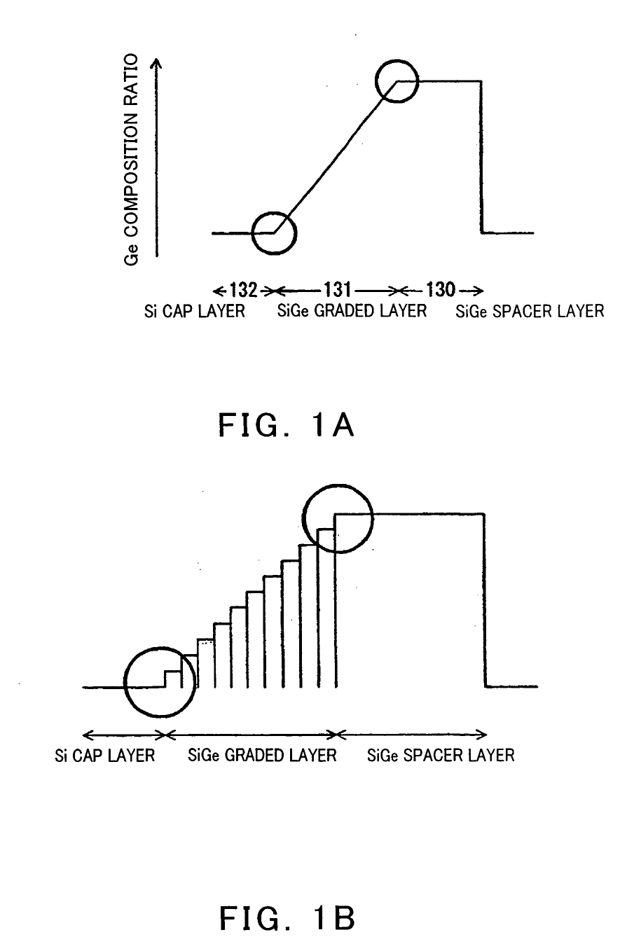

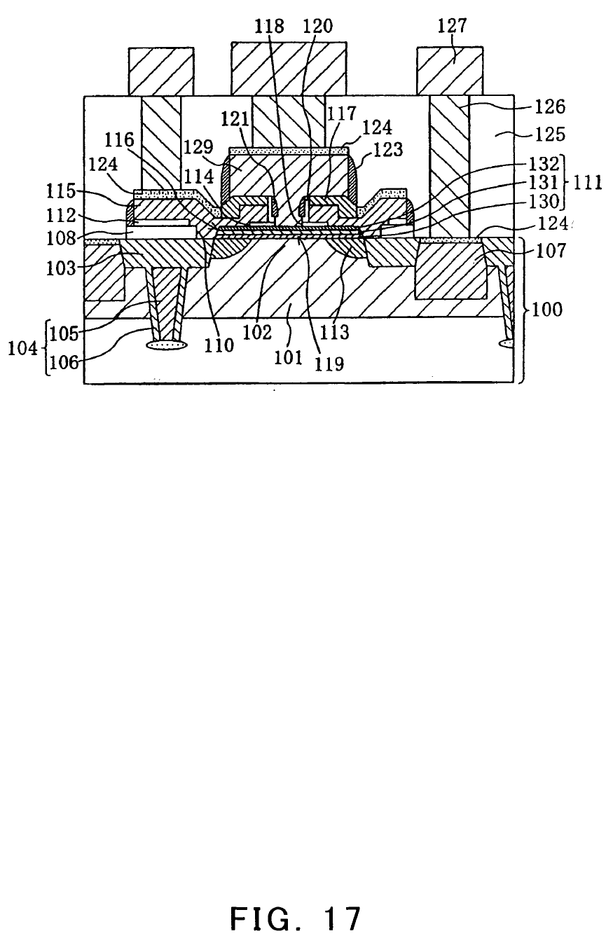

In order to improve measurement accuracy of film thickness of each of layers forming the base forming layer 111 in the conventional hetero bipolar transistor shown in FIG. 17, the present inventors paid attention to variation in Ge composition of the base forming layer 111 and made consideration as described below. Hereinbelow, the consideration will be described with reference to FIGS. 1A and 1B. FIGS. 1A and 1B are graphs respectively showing Ge composition of a base portion of the conventional hetero bipolar transistor and Ge composition of a base portion of a hetero bipolar transistor of the present invention.

As shown in FIG. 1A, in the SiGe graded layer 131 of the base forming layer 111, a Ge composition ratio continuously decreases in the direction from the SiGe spacer layer 130 to the Si cap layer 132. When the Ge composition ratio decreases in such a manner, there are no clear boundaries where the Ge composition varies discontinuously, between the Si cap layer 132 and the SiGe graded layer 131, and between the SiGe graded layer 131 the SiGe spacer layer 130. For this reason, the boundaries between the layers can not be accurately detected, from measurement using a spectroscopic ellipsometer, which makes it difficult to measure the film thickness of each layer.

Accordingly, in the present invention, as shown in FIG. 1B, Ge composition ratio of the SiGe graded layer of the base forming layer is made to decrease stepwisely in the direction from the SiGe space layer to the Si cap layer. Thereby, boundaries where the composition varies discontinuously are formed between the Si cap layer and the SiGe graded layer, and between the SiGe graded layer and the SiGe spacer layer. This allows the boundaries to be detected using the spectroscopic ellipsometer, and hence, the film thickness of each of the layers to be measured accurately.

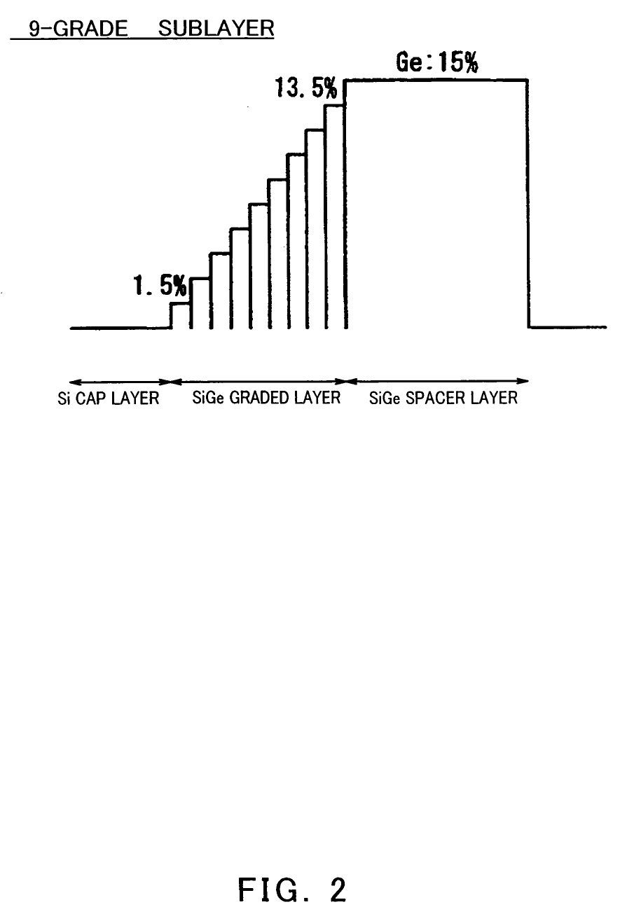

Based on the above consideration, the SiGe graded layer in which Ge composition ratio is made to vary stepwisely is formed and the film thicknesses of respective layers in the base forming layer are measured. The measurement results will be described with reference to FIGS. 2 to 5. The Ge composition ratio of the SiGe graded layer used in this measurement varies stepwisely from 0% to 15% in the direction from the SiGe spacer layer to the Si cap layer, and the film thickness of the SiGe graded layer is set to 40 nm. As used herein, a SiGe graded layer in which x layers having different Ge composition ratios are formed is referred to as an x-grade SiGe graded layer and each of the layers forming the x-grade SiGe graded layer is referred to as a sublayer.

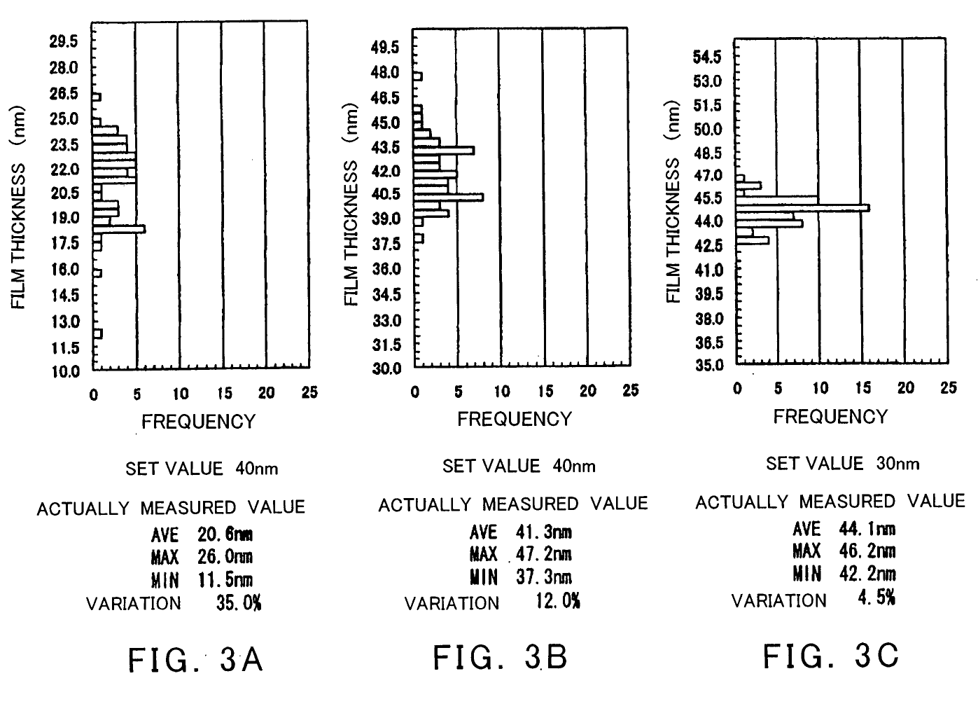

FIG. 2 is a view schematically showing variation in the Ge composition ratio of a SiGe graded layer composed of 9 sublayers according to the present invention. FIG. 3A is a view showing a result of the film thickness of the Si cap layer in the base forming layer of the present invention which is measured using the spectroscopic ellipsometer, and, likewise, FIGS. 3B and 3C are views respectively showing results of the film thickness of the SiGe graded layer and the film thickness of the SiGe spacer layer in the base forming layer which are measured using the spectroscopic ellipsometer. As shown in FIG. 2, in the case of the 9-grade SiGe graded layer, the film thickness of each of the sublayers in the SiGe graded layer is approximately 4.4 nm, and difference in the Ge composition ratio between adjacent sublayers is about 1.5%. In this case, as shown in FIGS. 3A to 3C, while the set value of the film thickness of the entire base forming layer is 110 nm (=40 nm+40 nm+30 nm), the actually measured value (AVE) is 106 nm (=20.6 nm+41.3 nm+44.1 nm). Thus, the actually measured value of the film thickness of the entire base forming layer is close to the set value. However, the actually measured values (AVE) of the film thicknes of the Si cap layer, the film thickness of the SiGe graded layer, and the film thickness of the SiGe spacer layer are respectively not close to the set values.

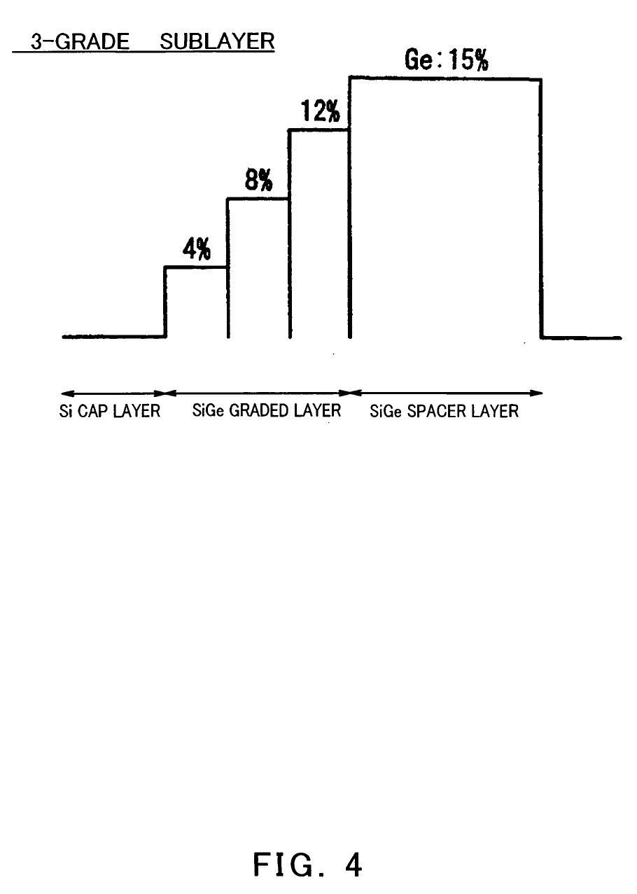

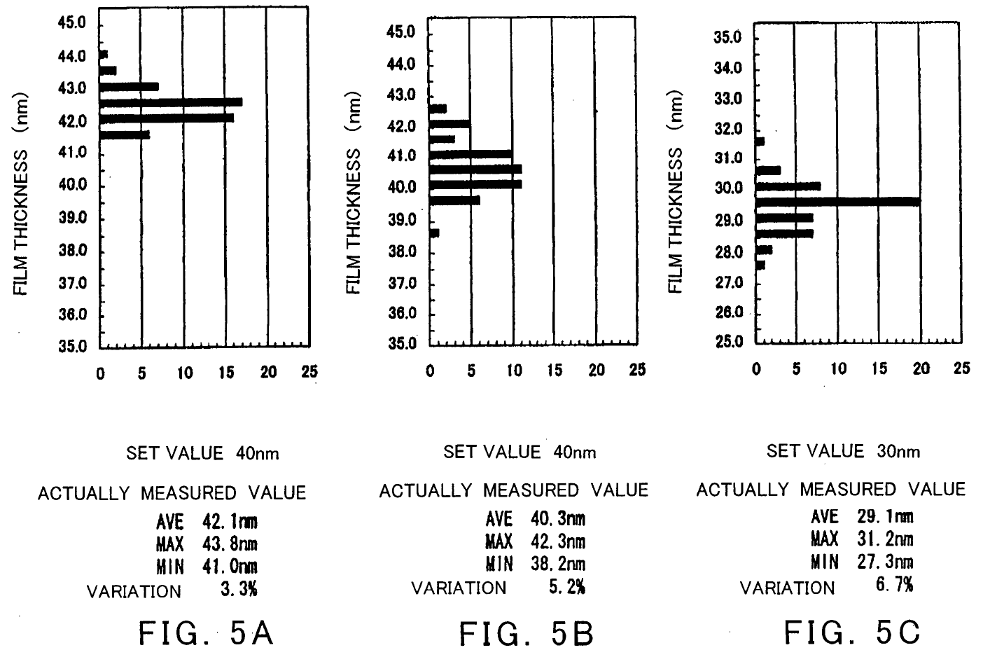

FIG. 4 is a view schematically showing variation in the Ge composition ratio of a SiGe graded layer composed of 3 sublayers of the present invention. FIG. 5A is a view showing a result of the film thickness of the Si cap layer in the base forming layer of the present invention, which is measured using the spectroscopic ellipsometer, and, likewise, FIGS. 5B and 5C are views respectively showing results of the film thickness of the SiGe graded layer and the film thickness of the SiGe spacer layer in the base forming layer which are measured using the spectroscopic ellipsometer. As shown in FIG. 4, in the case of the 3-grade SiGe graded layer, the film thickness of each of the sublayers in the SiGe graded layer is approximately 13.3 nm, and difference in the Ge composition ratio between adjacent sublayers is approximately in the range of 3% to 4%. In this case, as shown in FIGS. 5A to 5C, while the set value of the film thickness of the entire base forming layer is 110 nm (=40 nm+40 nm+30 nm), the actually measured value (AVE) is 111.5 nm (=42.1 nm+40.3 nm+29.1 nm). Thus, the actually measured value of the film thickness of the entire base forming layer is close to the set value. In addition, the actually measured values (AVE) of the film thickness of the Si cap layer, the film thickness of the SiGe graded layer, and the film thickness of the SiGe spacer layer are close to the set values, respectively.

As shown in FIG. 4, the Ge concentration of the SiGe spacer layer is set to 15% and the Ge concentrations of the SiGe graded layer in contact with the SiGe spacer layer are set to 12%, 8%, and 4% so as to decrease stepwisely. Alternatively, the Ge concentration of the SiGe spacer layer may be set to 20% and the Ge concentrations of the SiGe graded layer in contact with the SiGe spacer layer may set to 21%, 18%, and 8% so as to decrease stepwisely. In this case, preferably, the thickness of the SiGe spacer layer having a Ge concentration of 20% is approximately 20 nm, the thickness of a portion of the SiGe graded layer having a Ge concentration of 21% is approximately 4 nm, the thickness of a portion of the SiGe graded layer having a Ge concentration of 18% is approximately 4 nm, and the thickness of a portion of the SiGe graded layer having a Ge concentration of 8% is approximately 5 nm.

From the above results, it should be appreciated that the film thickness of each of the Si cap layer, the SiGe graded layer, and the SiGe spacer layer can be measured accurately by forming relatively less sublayers to increase the film thickness of each of the sublayers and by increasing difference in the Ge composition ratio between adjacent sublayers in the SiGe graded layer.

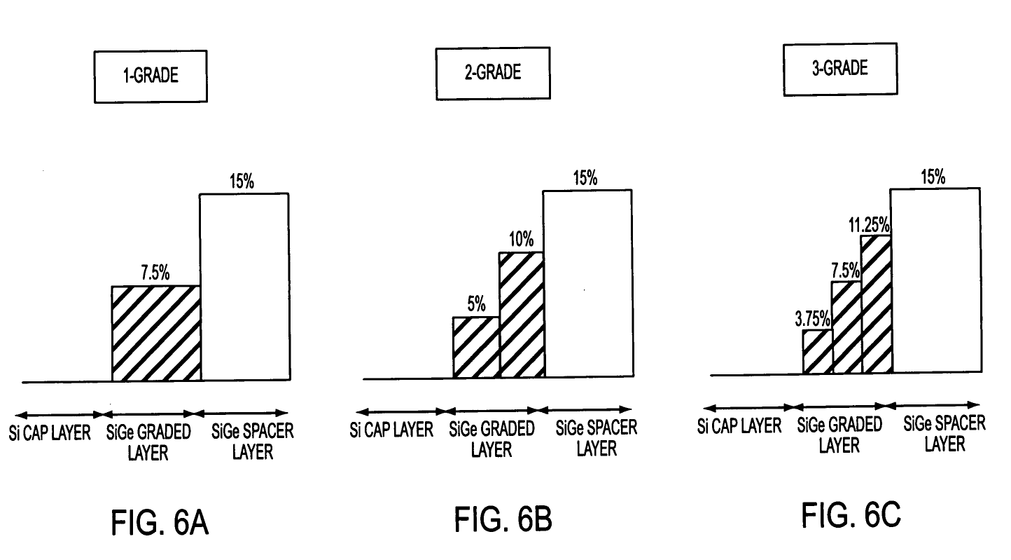

By the way, when the number of sublayers in the SiGe graded layer is set small based on the measurement results described above, the resulting device characteristic might be degraded because difference in the Ge composition ratio between adjacent sublayers becomes too large. Accordingly, the device characteristics relative to a different number of sublayers of SiGe graded layer are measured in order to find how many sublayers the SiGe graded layer can be divided into without degrading its device characteristic. Hereinbelow, measurement results will be described with reference to FIGS. 6 to 9. Here, Ge composition ratios of the SiGe graded layers used for measurement vary from 0% to 15% in the direction from the Si cap layer to the SiGe spacer layer, and the film thicknesses of the SiGe graded layers are set to 20 nm, 30 nm, and 40 nm, respectively.

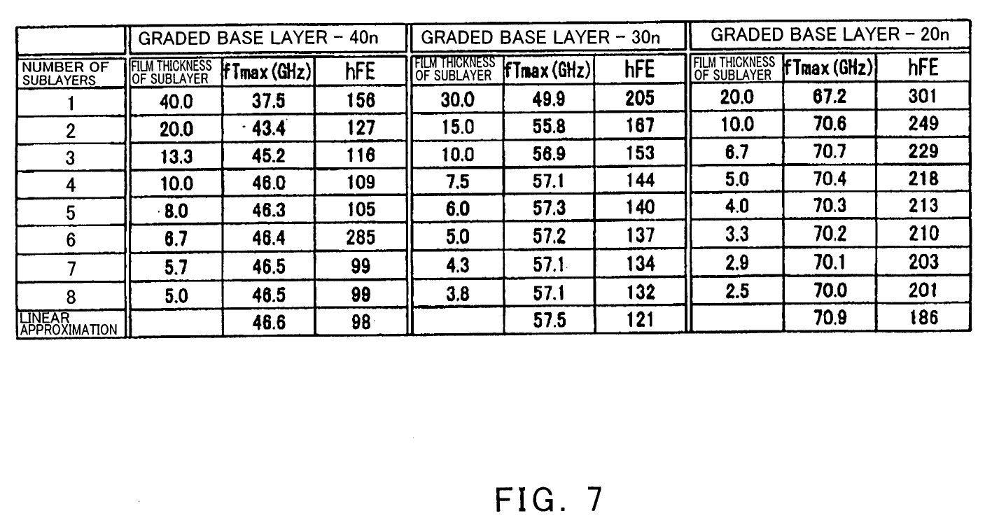

FIG. 6 is a view schematically showing sublayer patterns of the SiGe graded layers according to the present invention. FIG. 7 is a table listing measurement results of the device characteristics relative to a different number of sublayers composing the SiGe graded layers according to the present invention. As shown in FIG. 6, the Ge composition ratios of the sublayers in the SiGe graded layers and the film thicknesses of the sublayers are varied. Here, the Ge composition ratio of each of the SiGe graded layers is varied from 0% to 15% in the direction from the Si cap layer to the SiGe spacer layer. The film thickness of the Si cap layer is set to 30 nm, and the film thickness of the SiGe spacer layer (with the Ge composition ratio of 15%) is set to 40 nm. Although FIG. 6 shows only the case where the number of sublayers is from 1 to 3, the devices are fabricated in the same manner when the number of sublayers is 4 or more.

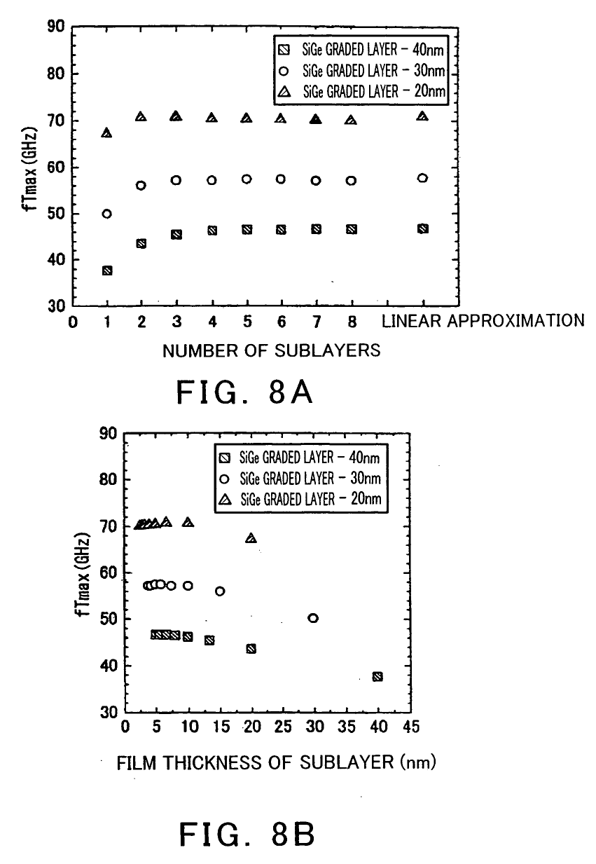

FIG. 8A is a graph showing the relationship between the number of sublayers and cut-off frequencies (fT) of devices measured by simulation. As can be seen from the graph, when the film thicknesses of the SiGe graded layer is 20 nm, 30 nm, and 40 nm, the cut-off frequencies of the devices become substantially constant when the number of sublayers is about 2, 3 or more. When the number of sublayers is 2, difference in the Ge composition ratio between adjacent sublayers is 5%, while when the number of sublayers is 3, difference in the Ge composition ratio between adjacent sublayers is 3.75%.

FIG. 8B is a graph showing the relationship between film thicknesses of sublayers in the SiGe graded layers and cut-off frequencies (fT) of devices measured by simulation. As can be seen from the graph, when the film thicknesses of the SiGe graded layers are 20 nm, 30 nm, and 40 nm, the cut-off frequencies of the devices become substantially constant when the film thicknesses of the sublayers in the SiGe graded layers are approximately 20 nm or less.

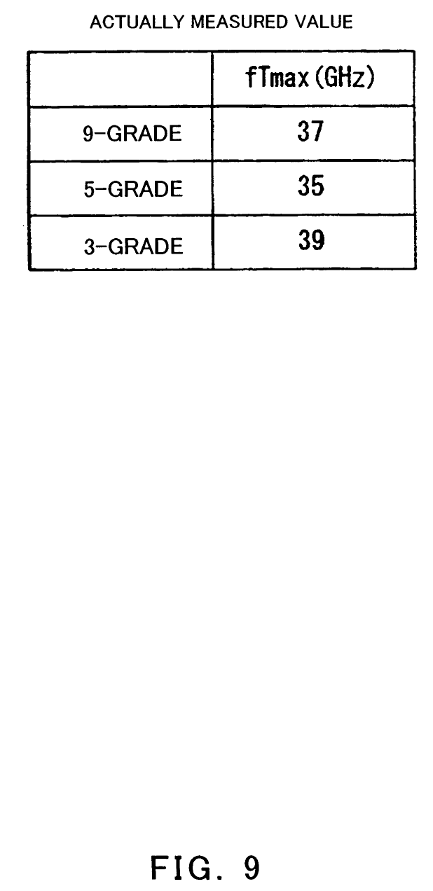

FIG. 9 is a table listing the number of sublayers in the SiGe graded layer having a thickness of 40 nm and measured values of the cut-off frequencies (fT) of the devices. The table shows that, when the number of sublayers is 3, 5, and 9, the device characteristics are not degraded because the variation in the cut-off frequency values is considered to be within the range of error.

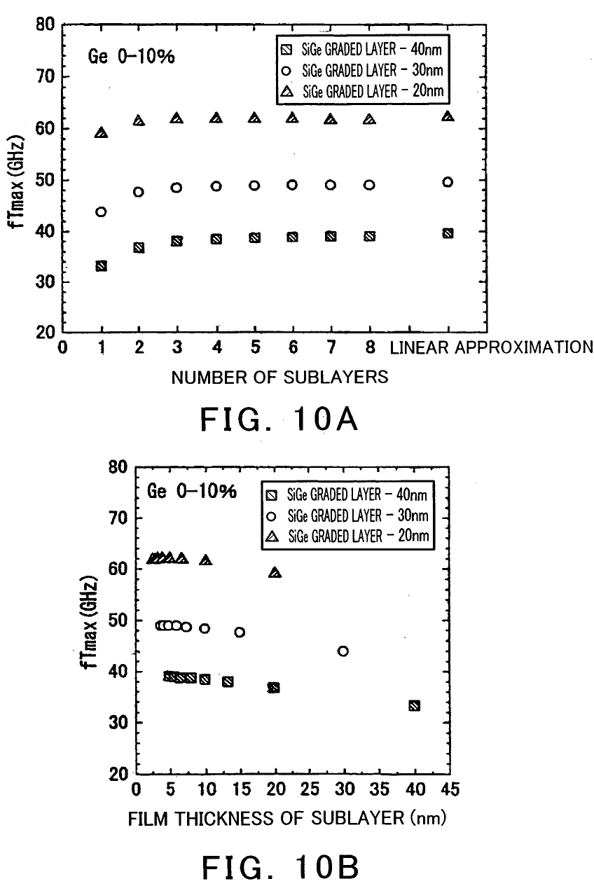

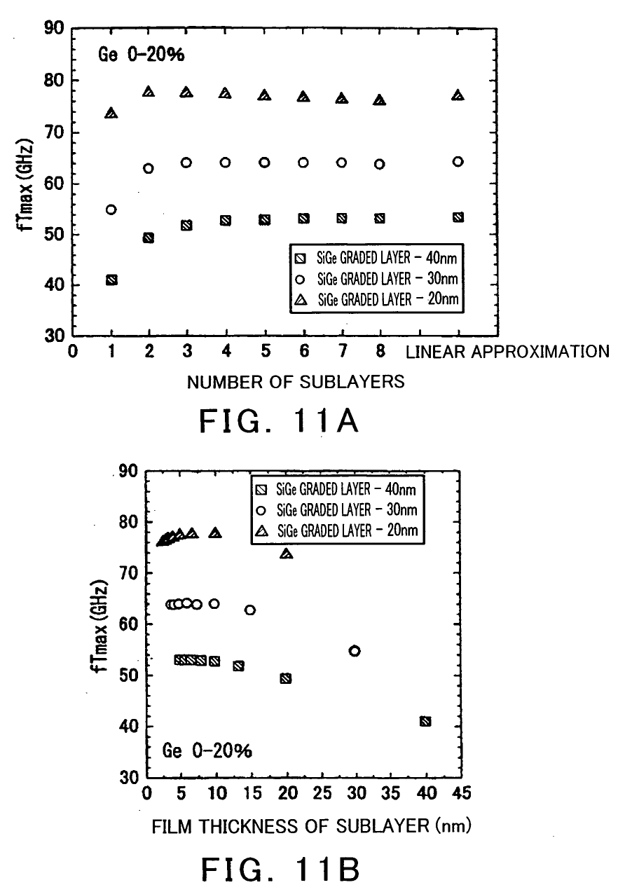

The above description has been given of the measurement results for the Ge composition ratio of the SiGe graded layer varying in the range of from 0% to 15%. Similar measurements are made for the case where the Ge composition ratio varies in the range from 0% to 10% and the Ge composition ratio varies in the range from 0% to 20%. Hereinbelow, the measurement results will be described with reference to FIGS. 10A and 10B and FIGS. 11A and 11B. FIG. 10A is a graph showing measurement results of the device characteristics relative to different number of sublayers composing SiGe graded layers having Ge composition ratios ranging from 0% to 10%. Likewise, FIG. 10B is a graph showing measurement results of the device characteristics relative to different sublayer thicknesses of SiGe graded layers having Ge composition ratios ranging from 0% to 10%. FIG. 11A is a graph showing measurement results of the device characteristic relative to different number of sublayers composing SiGe graded layers having Ge composition ratios raging from 0% to 20%. FIG. 11B is a graph showing measurement results of the device characteristic relative to different sublayer thicknesses of SiGe graded layers having Ge composition ratios raging from 0% to 20%.

As shown in FIG. 10A, when the Ge composition ratios of the SiGe graded layers vary from 0% to 10%, the cut-off frequencies (fT) of the devices become substantially constant when the number of sublayers is approximately 2 or 3,or more. Further, as shown in FIG. 10B, when the Ge composition ratios of the SiGe graded layers vary from 0% to 10%, the cut-off frequencies (fT) of devices become substantially constant when the film thicknesses of the sublayers in the SiGe graded layers are approximately 20 nm or less.

Similarly, as shown in FIG. 11A, when the Ge composition ratios of the SiGe graded layers vary from 0% to 20%, the cut-off frequencies (fT) of devices become substantially constant when the number of sublayers is approximately 2 or 3, or more. Furthermore, as shown in FIG. 11B, when the Ge composition ratios of the SiGe graded layers vary from 0% to 20%, the cut-off frequencies (fT) of the devices become substantially constant when the film thicknesses of the sublayers of the SiGe graded layers are approximately 20 nm or less.

From the above described results, it should be appreciated that, when the variation range of the Ge composition ratios of the Si Ge graded layer is from 0% to 15%, from 0% to 10%, and from 0% to 20%, the number of sublayers in the SiGe graded layer should be 2 or 3 or more and the film thickness of each sublayer should be approximately 20 nm or less, in order to inhibit degradation of the device characteristic.

In summary, according to the present invention, in order to measure the film thickness of the SiGe spacer layer, the film thickness of the SiGe graded layer and the film thickness of the Si cap layer, it is preferable that the film thickness of each sublayer in the SiGe graded layer is thick, the number of sublayers is small, and difference in the Ge composition ratio between adjacent sublayers is approximately 2.5% or more. It should be appreciated that, to avoid degradation of the device characteristic, the film thickness of each sublayer in the SiGe graded layer needs to be 20 nm or less, or the number of sublayers needs to be 2 or more.

As described above, by setting difference in the Ge composition ratio between adjacent sublayers to approximately 2.5% or more, the boundary between the layers can be detected. As a result, the film thickness of the SiGe spacer layer, the film thickness of the SiGe graded layer, and the film thickness of the Si cap layer can be accurately measured using the spectroscopic ellipsometer. By the way, the spectroscopic ellipsometer is configured to measure the film thickness of each layer based on an output depending on bandgap. However, if the graded layer contains carbon, then the bandgap of the graded layer is narrowed. For this reason, the Ge composition ratio of the graded layer needs to be set higher than that of the graded layer that does not contain carbon in order to detect the boundary between adjacent layers. Because it is possible to detect the boundary between adjacent layers when the bandgap difference between adjacent sublayers is 18 meV or more, the Ge composition ratios of sublayers may be decided so as to achieve that bandgap difference.

### Embodiment 1

In this embodiment, a hetero bipolar transistor having a SiGe graded layer in which Ge composition ratio varies stepwisely will be described based on the above described consideration and measurement results.

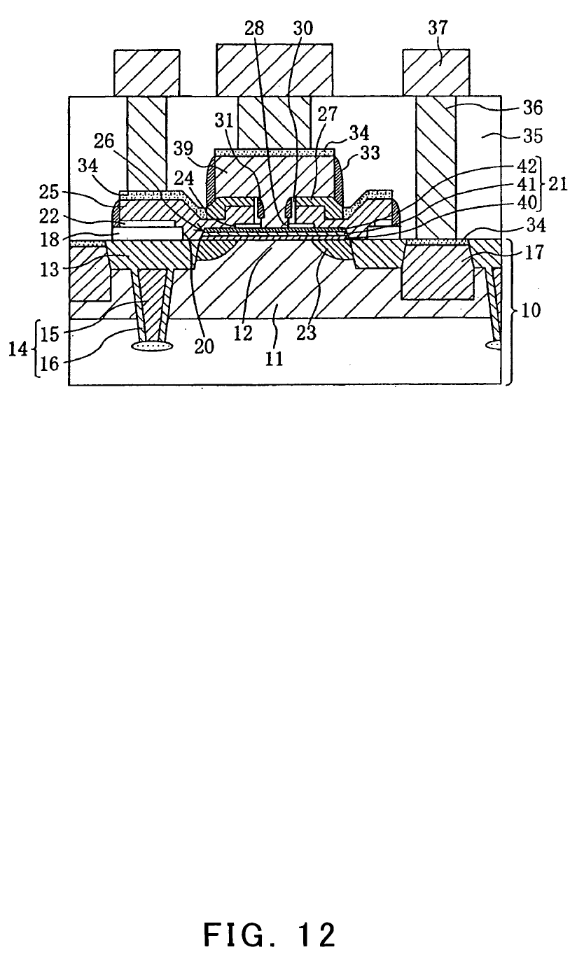

First of all, a structure of the hetero bipolar transistor according to the present invention will be described with reference to FIG. 12. FIG. 12 is a cross-sectional view showing the structure of the hetero bipolar transistor according to the embodiment 1 of the present invention.

As shown in FIG. 12, in the hetero bipolar transistor according to the present embodiment, an upper portion of a Si substrate 10 has a retrograde well 11 having a depth of 1 μm and containing an N-type impurity. As isolation, a shallow trench 13 in which silicon oxide is embedded and a deep trench 14 comprised of an undoped polysilicon film 15 and a silicon oxide film 16 surrounding the undoped polysilicon film 15 are provided.

A collector layer 12 is provided in a region within the Si substrate 10 which is sandwiched between shallow trenches 13. An n⁺ collector plug layer 17 is provided in a region of the Si substrate 10 which is isolated from the collector layer 12 by the shallow trench 13, for connection to an electrode of the collector layer 12 through the retrograde well 11.

A first deposited oxide film 18 having a collector opening 20 with a thickness of approximately 30 nm is provided on the Si substrate 10. A base forming layer 21 comprised of a SiGe spacer layer 40 having a set thickness value of 40 nm, a SiGe graded layer 41 having a set thickness value of 40 nm, and a Si cap layer 42 having a set thickness value of 30 nm is formed on a portion of an upper surface of the Si substrate 10 exposed to the collector opening 20. The base forming layer 21 is formed by selective growth only on a portion of the Si substrate 10 exposed to the collector opening 20. A lower portion of a center portion of the base forming layer 21 functions as an intrinsic base 29, while an upper portion of the center portion of the base forming layer 21 functions as an emitter layer. Most of the SiGe spacer layer 40 and the SiGe graded layer 41 in the base forming layer 21 are doped with a p-type impurity such as boron (B) at approximately 2×10¹⁸ atoms·cm⁻³, while the Si cap layer 42 is doped by diffusion of an n-type impurity such as phosphorous (P) from an n⁺ polysilicon layer 39 in the distribution from 1×10²⁰ atoms·cm⁻³ to 1×10¹⁷ atoms·cm⁻³ from top to bottom in a depth direction of the substrate.

In the present invention, the SiGe graded layer 41 of the base forming layer 21 is composed of a plurality of sublayers having a substantially equal thickness. The Ge composition ratios of the sublayers of the SiGe graded layer 41 vary stepwisely at a substantially constant rate within a range of 0% to 15% in a direction from the SiGe spacer layer 40 to the Si cap layer 42. That is, the SiGe graded layer 41 is composed of a plurality of sublayers having different Ge composition ratios.

Based on the above described consideration and the measurement results, in order to accurately measure the film thickness of the Si cap layer 42, the film thickness of the SiGe graded layer 41, and the film thickness of the SiGe spacer layer 40, it is preferable that the number of sublayers in the SiGe graded layer 41 is smaller, the film thickness of each sublayer is thicker, and difference in the Ge composition ratio between adjacent sublayers is larger. However, to maintain the device characteristic, it is necessary that the number of sublayers should be 2 or more, or the film thickness of each sublayer should be approximately 20 nm or less. If the number of sublayers is too large, then the film thickness of each sublayer becomes too small, so that the thicknesses of the layers can not be accurately measured. For this reason, the number of sublayers is preferably 6 or less.

The Si cap layer 42, the SiGe graded layer 41, and the SiGe spacer layer 40 of the base forming layer 21 are epitaxially grown by CVD (Chemical Vapor Deposition) process using SiH₄, Si₂H₆, and GeH₄, for example, as source gases. Among them, when the SiGe graded layer 41 is formed, sublayers having different Ge composition ratios are formed by stepwisely changing the supply ratio between the Si material gas and the Ge material gas of the material gases.

A second deposited oxide film 22 having a thickness of 30 nm and functioning as an etching stopper is provided on the first deposited oxide film 18 and the base forming layer 21. A base junction opening 24 and a base opening 28 are formed in the second deposited oxide film 22. And, a p⁺ polysilicon layer 25 having a thickness of approximately 150 nm and a third deposited oxide film 27 are provided such that the p⁺ polysilicon layer 25 extends over the second deposited oxide film 22 to fill the base junction opening 24. A portion of the base forming layer 21 excluding a region located below the base opening 28 and the p⁺ polysilicon layer 25 form an extrinsic base 26.

Portions of the p⁺ polysilicon layer 25 and the third deposited oxide film 27 located above the base opening 28 of the second deposited oxide film 22 are configured to open. Fourth deposited oxide films 30 having a thickness of approximately 30 nm are formed on side faces of the p⁺ polysilicon layer 25. On the fourth deposited oxide films 30, side walls 31 made of polysilicon and having a thickness of approximately 100 nm are provided. An n⁺ polysilicon layer 39 extends over the third deposited oxide film to fill the base opening 28. The n⁺ polysilicon layer 39 functions as an emitter plug electrode. Outer side faces of the n⁺ polysilicon layer 39 and the p⁺ polysilicon layer 35 are covered with side walls 33.

Ti (titanium) silicide layers 34 are formed on surfaces of the n⁺ collector plug layer 17, the p⁺ polysilicon layer 25, and the n⁺ . polysilicon layer 39, respectively.

The entire substrate is covered with an interlayer dielectric 35. Through the interlayer dielectric 35, contact holes respectively extend to reach the n⁺ collector plug layer 17, the p⁺ polysilicon layer 25 as part of the extrinsic base, and the Ti silicide layer 34 of the n⁺ polysilicon layer 39 as the emitter plug electrode. The contact holes are filled with W plugs 36. Metal wires 37 are connected to the W plugs 36 and extend on the interlayer dielectric 35. The hetero bipolar transistor according to the present invention is constructed as described above.

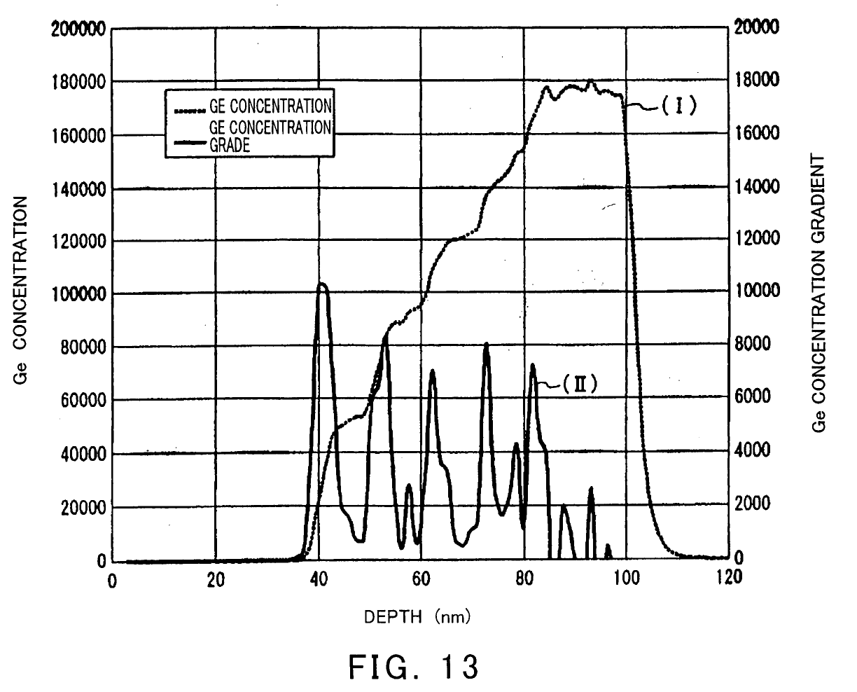

Hereinbelow, measurement results of the varying Ge composition ratios of the SiGe graded layer 41 according to the present invention will be described with reference to FIG. 13. FIG. 13 is a graph showing results of the variation in Ge composition ratio of the SiGe graded layer according to the embodiment 1 of the present invention which are measured using SIMS (Secondary Ion Mass Spectroscopy). Here, the SiGe graded layer 41 has a film thickness of 40 nm, has Ge composition ratio varying within a range of 0% to 15%, and is composed of 4 sublayers.

In FIG. 13, a broken curve (I) represents an intensity profile of SIMS, and a solid curve (II) represents a first derivative profile of the broken curve (I). As can be seen from the broken curve (I) and the solid curve (II), the Ge composition ratio of the SiGe graded layer varies discontinuously, and therefore, the boundaries of the sublayers can be detected.

Hereinbelow, effects obtained by the hetero bipolar transistor of the present embodiment will be described.

According to the hetero bipolar transistor of this embodiment, in the SiGe graded layer 41 of the base forming layer 21, the Ge composition ratio is made to increase stepwisely in a direction from the Si cap layer 42 to the SiGe spacer layer 40. Thereby, boundaries are formed between the Si cap layer 42 and the SiGe graded layer 41, and between the SiGe graded layer 41 and the SiGe spacer layer 40 due to differences in the composition ratios, thereby allowing the boundaries to be detected using the spectroscopic ellipsometer. Therefore, accurate measurements of the film thicknesses of the layers becomes easy. Consequently, in the mass-production of the devices, accurate confirmation and control of layer formation can easily be performed.

In this embodiment, variation range of the Ge composition ratio of the SiGe graded layer 41 is not intended to be limited to the above described range of 0% to 15%. For example, the range may be from 0% to 10% or from 0% to 30%.

Further, the set value of the film thickness of the SiGe spacer layer. 40, the set value of the film thickness of the SiGe graded layer 41, and the set value of the film thickness of the Si cap layer 42 in the base forming layer 21 are not intended to be limited to those described above, but other set values may be adopted.

### Embodiment 2

In an embodiment 2, an example of a modified pattern of the base forming layer in the hetero bipolar transistor (HBT) described in the embodiment 1, will be described.

The HBT according to this embodiment is identical in structure to the HBT described in the embodiment 1 except that the pattern of the base forming layer 21 is different.

Hereinbelow, first to third examples of the base forming layer 21 according to this embodiment will be described with reference to FIGS. 14A to 16C and FIG. 11.

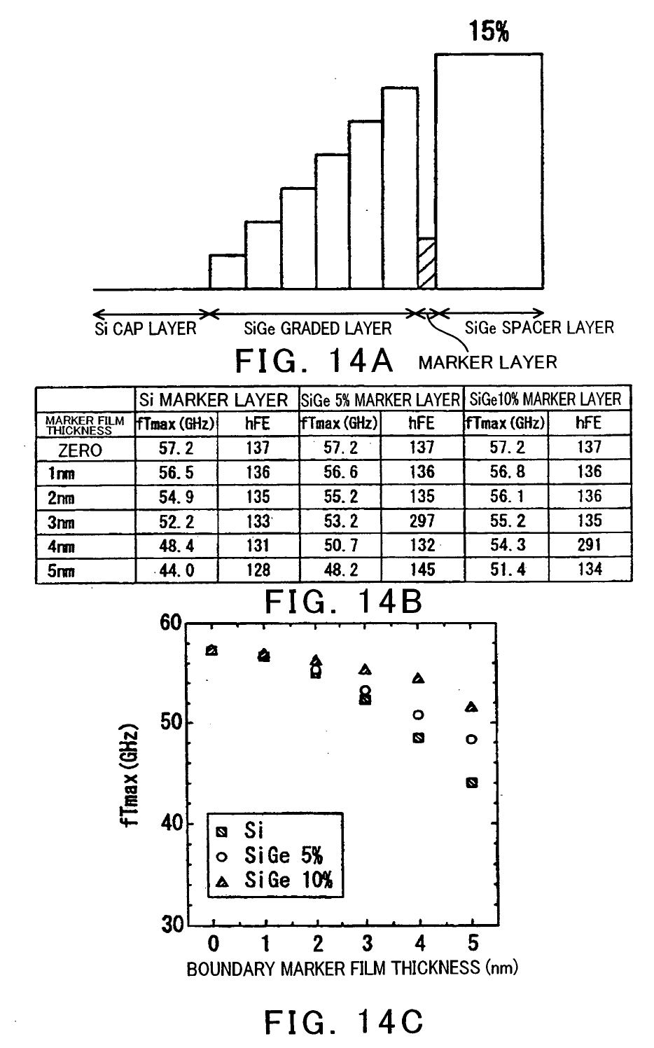

FIG. 14A is a view schematically showing Ge composition ratios of sublayers in a base forming layer 21 in a first example, FIG. 14B is a table listing measurement results of device characteristic in the first example, and FIG. 14C is a graph showing measurement results of the device characteristic in the first example.

As shown in FIG. 14A, the first base forming layer 21 according to this embodiment includes the Si cap layer 42, the SiGe graded layer 41 composed of sublayers having Ge composition ratios that decrease within the range from 0% to 15% in a direction from the SiGe spacer layer 40 to the Si cap layer 42, the SiGe spacer layer 40, and a marker layer disposed between the SiGe graded layer 41 and the SiGe spacer layer 40. The marker layer is either a layer made of Si or a layer comprised of a SiGe layer having a Ge composition ratio of 5% or 10%. Thus, a boundary between the SiGe graded layer 41 and the SiGe spacer layer 40 can be defined by disposing the marker layer having the Ge composition ratio lower than that of the SiGe spacer layer 40 between the SiGe graded layer 41 and the SiGe spacer layer 40. Alternatively, the Ge composition ratio of the marker layer may be higher than that of the SiGe spacer layer 40. As mentioned previously, the boundary between the layers can be accurately measured if difference in the Ge composition ratio between the layers is approximately 2.5% or more. Therefore, in the first example, if the difference between the Ge composition ratio of the marker layer and the Ge composition ratio of the SiGe spacer layer 40 is approximately 2.5% or more, the boundary between the SiGe graded layer 41 and the SiGe spacer layer 40 can be defined.

In this case, as shown in FIGS. 14B and 14C, when the film thickness of the marker layer is approximately 3 nm or less, degradation of the device characteristic hardly occurs.

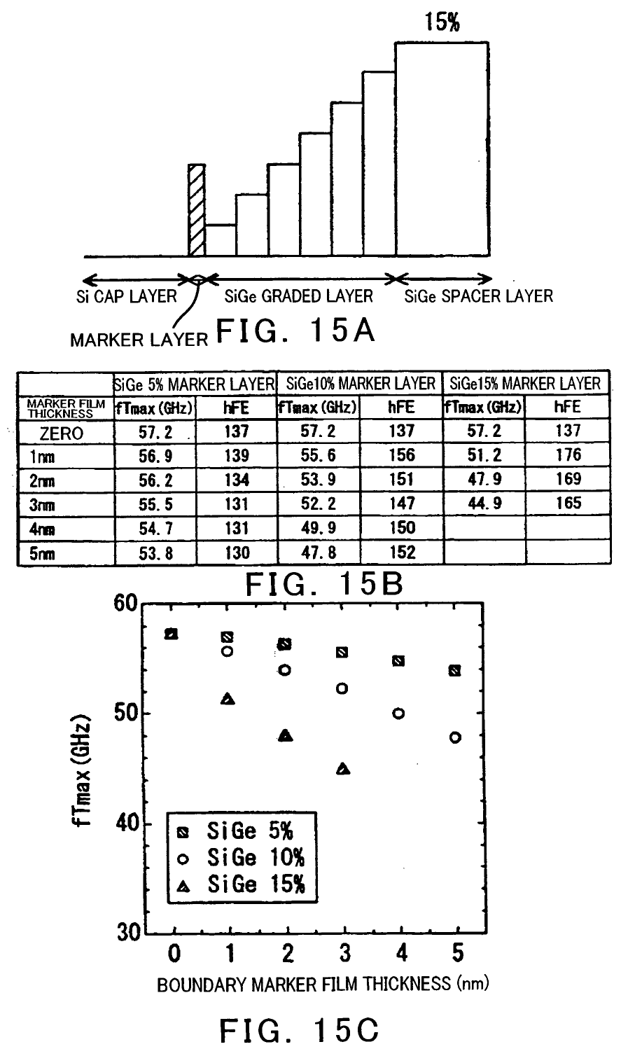

FIG. 15A is a view schematically showing Ge composition ratios of sublayers of the base forming layer 21 in a second example, FIG. 15B is a table listing measurement results of device characteristic in the second example, and FIG. 15C is a graph showing measurement results of the device characteristic in the second example.

As shown in FIG. 15A, a second base forming layer according to this embodiment includes the Si cap layer 42, the SiGe graded layer 41 composed of sublayers having Ge composition ratios that decrease within the range from 0% to 15% in the direction from the SiGe spacer layer 40 to the Si cap layer 42, the SiGe spacer layer 40, and the marker layer disposed between the Si cap layer 42 and the SiGe graded layer 41. The marker layer is comprised of a SiGe layer having a Ge composition ratio of 5%, 10%, or 15%. Thus, a boundary between the Si cap layer 42 and the SiGe graded layer 41 can be defined by disposing the marker layer having the Ge composition ratio higher than that of the Si cap layer 42. As described above, the boundaries between the layers can be accurately measured if the difference in Ge composition ratio between the layers is approximately 2.5% or more. Therefore, in the second example, if the difference in Ge composition ratio between the marker layer and the SiGe graded layer 41 is approximately 2.5% or more, the boundary between the Si cap layer 42 and SiGe graded layer 41 can be defined.

In this case, as shown in FIGS. 15B and 15C, especially when the Ge composition ratio of the marker layer is low, degradation of the device characteristic hardly occurs if the film thickness of the marker layer is approximately 3 nm or less.

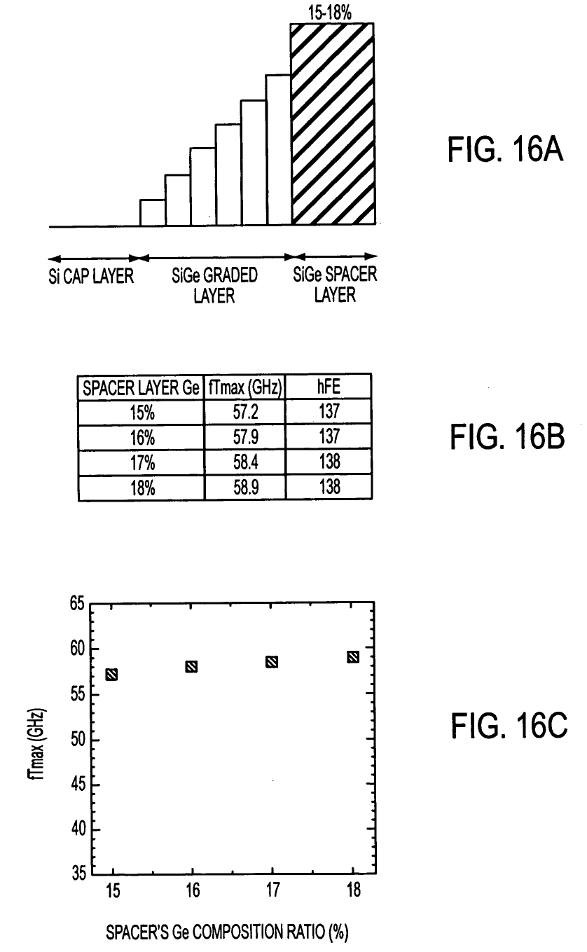

FIG. 16A is a view schematically showing Ge composition ratios of sublayers of the base forming layer 21 in a third example, FIG. 16B is a table listing measurement results of device characteristic in the third example, and FIG. 16C is a graph showing measurement results of the device characteristic in the third example.

As shown in FIG. 16A, a third base forming layer according to this embodiment includes the Si cap layer 42, the SiGe graded layer 41 composed of sublayers having Ge composition ratios that decrease within the range from 0% to 15% in the direction from the SiGe spacer layer 40 to the Si cap layer 42, and the SiGe spacer layer 40 having a Ge composition ratio of 15% or more. Here, the Ge composition ratio of the SiGe spacer layer 40 is in the range of 15% to 18%. The use of the SiGe spacer layer 40 having a high Ge composition ratio makes difference in the Ge composition ratio between the SiGe graded layer 41 and the SiGe spacer layer 40 large, thereby allowing the boundary between the SiGe spacer layer 40 and the SiGe graded layer 41 to be defined.

In this case, as shown in FIGS. 16B and 16C, degradation of the device characteristic does not occur even when the Ge composition ratio of the SiGe spacer layer 40 is increased up to 18%. Therefore, it becomes possible to measure the film thicknesses of the layers forming the base forming layer more accurately without degrading the device.

### Other Embodiments

While, in the above described embodiments, the SiGe layer is used as the graded layer 41 forming the base portion, a SiGeC (silicon germanium carbon) layer may be used.

While, in the above described embodiments, the sublayers of the SiGe layer 41 have a substantially equal thickness, the thicknesses of the sublayers of the SiGe graded layer 41 may be equal to one another or different from one another.

While, in the above described embodiments, the Ge composition ratios of the sublayers of the SiGe graded layer 41 increase at a constant rate in the direction from the Si cap layer 42 to the SiGe spacer layer 40, the Ge composition ratios does not necessarily increase at a constant rate. For example, if the Ge composition ratio of a sublayer of the SiGe graded layer 41 which is in contact with the Si cap layer 42 is higher than the Ge composition ratio of the Si cap layer 42 by approximately 2.5% or more, then the boundary between the Si cap layer 42 and the SiGe graded layer 41 can be accurately detected. Similarly, if the Ge composition ratio of a sublayer of the SiGe graded layer 41 which is in contact with the SiGe spacer layer 40 is lower than the Ge composition ratio of the SiGe spacer layer 40 by approximately 2.5% or more, the boundary between the SiGe graded layer 41 and the SiGe spacer layer 40 can be accurately detected.

Numerous modifications and alternative embodiments of the present invention will be apparent to those skilled in the art in view of the forgoing description. Accordingly, the description is to be construed as illustrative only, and is provided for the purpose of teaching those skilled in the art the best mode of carrying out the invention. The details of the structure and/or function may be varied substantially without departing from the spirit of the invention.

What is claimed is:

1. A hetero bipolar transistor comprising:
a semiconductor substrate;
a first semiconductor layer formed on the semiconductor substrate and comprised of a crystal containing silicon and germanium;
a second semiconductor layer formed on the first semiconductor layer and comprised of a crystal containing silicon and germanium, at least a portion of the second semiconductor layer functioning as a base layer; and
a third semiconductor layer formed on the second semiconductor layer and comprised of a crystal containing silicon, at least a portion of the third semiconductor layer functioning as an emitter layer, wherein the second semiconductor layer includes regions each having a germanium composition ratio that varies stepwisely with a difference of 2.5% or more, in the vicinity of a boundary between the first semiconductor layer and the second semiconductor layer and a boundary between the second semiconductor layer and the third semiconductor layer.

2. A hetero bipolar transistor comprising:
a semiconductor substrate;
a first semiconductor layer formed on the semiconductor substrate and comprised of a crystal containing silicon and germanium;
a second semiconductor layer formed on the first semiconductor layer and comprised of a crystal containing silicon and germanium, at least a portion of the second semiconductor layer functioning as a base layer; and
a third semiconductor layer formed on the second semiconductor layer and comprised of a crystal containing silicon, at least a portion of the third semiconductor layer functioning as an emitter layer, wherein the second semiconductor layer includes a region having a germanium composition ratio that varies stepwisely with a difference of 2.5% or more, in the vicinity of a boundary between the first semiconductor layer and the second semiconductor layer.

3. A hetero bipolar transistor comprising:
a semiconductor substrate;
a first semiconductor layer formed on the semiconductor substrate and comprised of a crystal containing silicon and germanium;
a second semiconductor layer formed on the first semiconductor layer and comprised of a crystal containing silicon and germanium, at least a portion of the second semiconductor layer functioning as a base layer; and
a third semiconductor layer formed on the second semiconductor layer and comprised of a crystal containing silicon, at least a portion of the third semiconductor layer functioning as an emitter layer, wherein the second semiconductor layer includes a region having a germanium composition ratio that varies stepwisely with a difference of 2.5% or more, in the vicinity of a boundary between the second semiconductor layer and the third semiconductor layer.

4. The hetero bipolar transistor according to claim 1, wherein the second semiconductor layer contains silicon, germanium, and carbon.

5. The hetero bipolar transistor according to claim 1, wherein the second semiconductor layer is comprised of a plurality of sublayers having different germanium composition ratios, and the number of the sublayers is not less than 2 and not more than 6.

6. The hetero bipolar transistor according to claim 1, further comprising a marker layer formed between the first semiconductor layer and the second semiconductor layer, wherein the marker layer has a germanium composition ratio higher or lower than a germanium composition ratio of the first semiconductor layer by 2.5% or more and is comprised of a crystal containing at least silicon and germanium.

7. The hetero bipolar transistor according to claim 1, further comprising a marker layer formed between the second semiconductor layer and the third semiconductor layer, wherein the marker layer has a germanium composition ratio higher than a germanium composition ratio of the third semiconductor layer by 2.5% or more and is comprised of a crystal containing at least silicon and germanium.

8. A hetero bipolar transistor comprising:
a semiconductor substrate;
a first semiconductor layer formed on the semiconductor substrate and comprised of a crystal containing silicon and germanium;
a second semiconductor layer formed on the first semiconductor layer and comprised of a crystal containing silicon and germanium, at least a portion of the second semiconductor layer functioning as a base layer; and
a third semiconductor layer formed on the second semiconductor layer and comprised of a crystal containing silicon, at least a portion of the third semiconductor layer functioning as an emitter layer,
wherein the second semiconductor layer includes regions each having a bandgap that varies stepwisely with a difference of 18 meV or more, in the vicinity of a boundary between the first semiconductor layer and the second semiconductor layer and a boundary between the second semiconductor layer and the third semiconductor layer.

9. A method of measuring a thickness of a semiconductor layer in a hetero bipolar transistor including:
a semiconductor substrate;
a first semiconductor layer formed on the semiconductor substrate and comprised of a crystal containing silicon and germanium, the germanium having a constant concentration;
a second semiconductor layer formed on the first semiconductor layer and comprised of a crystal containing silicon and germanium, at least a portion of the second semiconductor layer functioning as a base layer; and
a third semiconductor layer formed on the second semiconductor layer and comprised of a crystal containing silicon, at least a portion of the third semiconductor layer functioning as an emitter layer,
the method comprising measuring a thickness of the second semiconductor layer,
wherein the second semiconductor layer is comprised of a plurality of sublayers,
a composition ratio of germanium contained in a first sublayer is different from a composition ratio of germanium contained in a second sublayer adjacent to the first sublayer, and
a first boundary between the first semiconductor layer and a sublayer of the second semiconductor layer which is adjacent to the first semiconductor layer, where the composition ratio of germanium varies discontinuously, and a second boundary between the third semiconductor layer and a sublayer of the second semiconductor layer which is adjacent to the third semiconductor layer, where composition ratio of germanium varies discontinuously, are detected by using a spectroscopic ellipsometer, to define a distance between the first boundary and the second boundary as the thickness of the second semiconductor layer.

10. The method of measuring a thickness of a semiconductor layer in a hetero bipolar transistor according to claim 9, wherein each of the plurality of sublayers contains germanium of a composition ratio of 1.5 % or more, and a difference in composition ratio between the germanium contained in the first sublayer and a composition ratio of the germanium contained in the second sublayer is 1.5% or more.

11. The method of measuring a thickness of a semiconductor layer in a hetero bipolar transistor according to claim 9, wherein each of the plurality of sublayers contains germanium of a composition ratio of 2.5 % or more, and a difference in composition ratio between the germanium contained in the first sublayer and the germanium contained in the second sublayer is 2.5% or more.
